(19) United States
(12) Patent Application Publication
(10) Pub. No.: US 2026/0363096 A1
(43) Pub. Date: Nov. 12, 2026

(54) SEMICONDUCTOR POWER MODULE AND METHOD FOR MANUFACTURING A SEMICONDUCTOR POWER MODULE

(71) Applicant: Hitachi Energy Ltd, Zürich (CH)

(72) Inventors: Dominik TRUESSEL, Bremgarten (CH); Milad MALEKI, Untersiggenthal (CH); Lluis SANTOLARIA, Olten (CH)

(21) Appl. No.: 19/102,938

(22) PCT Filed: Aug. 18, 2022
(86) PCT No.: PCT/EP2022/073049

§ 371 Date: Feb. 11, 2025

(51) Int. Cl. H10W 70/40; H10W 70/04; H10W 76/05

(52) U.S. Cl. CPC H10W 70/433; H10W 70/047; H10W 70/429; H10W 76/05

(57) ABSTRACT

A semiconductor power module (10) comprises a substrate (4) and at least one terminal (2) that is electrically coupled to the substrate (4). The semiconductor power module (10) further comprises a reinforcement member (3) that comprises a material different from a material of the at least one terminal (2), and a housing with a molded body (1). The molded body (1) surrounds the substrate (4) , the reinforcement member (3) and the at least one terminal (2) such that the at least one terminal (2) is integrally coupled and embedded in the molded body (1) and partially protrudes from a wall (5) of the molded body (1). The reinforcement member (3) is mechanically coupled to the at least one terminal (2) such that it is at least in part integrally coupled and embedded in the molded body (1) at the position the at least one terminal (2) protrudes from the wall (5) of the molded body (1).

The present disclosure is related to a semiconductor power module and a corresponding manufacturing method for a semiconductor power module.

Conventional semiconductor power packages comprise a respective housing with electrical connections. In this respect, it is a general challenge to contribute to a stable housing, secure electrical connections and a reliable functioning of semiconductor power package.

Embodiments of the present disclosure can provide a semiconductor power module with improved stability and reliable functioning even for high voltage power module applications. Further embodiments of the present disclosure can provide a manufacturing method for such a semiconductor power module.

According to an embodiment, a semiconductor power module comprises a substrate and at least one terminal that is electrically coupled to the substrate. The semiconductor power module further comprises a reinforcement member that comprises a material different from a material of the at least one terminal. The semiconductor power module further comprises a housing realized as a molded body or comprising a molded body that surrounds the substrate, the reinforcement member and the at least one terminal such that the at least one terminal is integrally coupled and embedded in the molded body and partially protrudes from a wall of the molded body.

The material of the reinforcement member is also different from a material of the molded body. The reinforcement member is mechanically coupled to the at least one terminal such that it is also integrally coupled and embedded in the molded body in part at least at the position or in an area the at least one terminal protrudes from the wall of the molded body. The position basically defines a region inside the molded body close to the protruding terminal section. The position does not necessarily have to be exact at the boundary between the terminal and the wall of molded body.

The one or more terminals may act as power terminals or as auxiliary terminals, e.g. used for signal wiring. The one or more terminals can be made of or comprise cooper or copper alloy. The one or more terminals can comprise partly or completely a coating of one or more layers made of or comprising nickel, gold, silver and/or other metals.

The housing may be formed as a molded block comprising e.g. a predetermined cuboid. The molded body can be formed out of thermoplastic or thermosetting resin, or any other resin material. The molded body can be formed by means of injection molding, transfer molding and/or any other applicable molding process. The molded body can comprise a material that contains fillers like particles or fibers. The molded body of the housing can partially or completely enclose components of the semiconductor power module, e.g. the substrate, the one or more terminals and/or the reinforcement member. The molded body can directly cover a section of the aforementioned components or indirectly with one or more elements in between. The at least one terminal is partially enclosed in the molded body and provides an exposed portion serving as an electrical connector. The wall of the molded body the one or more terminals protrude from can form a side wall, for example, with respect to lateral directions and a stacking direction of the semiconductor power module. The lateral directions may realize horizontal directions and may relate to the main plane of extent of the semiconductor power module whereas the stacking direction realize a vertical direction perpendicular to the lateral directions. The housing can comprise further elements to the molded body and may realize a frame or cover of a resin or gel filled power module with one or more embedded terminals. According to such a configuration, the molded body forms a frame and/or a cover of the gel filled power module.

The substrate can be formed as a leadframe. For example, the substrate is realized as an insulated metal substrate with a metal top layer, a metal bottom and a dielectric resin layer in between. The resin layer can be formed as a pre-peg sheet or a molded epoxy resin layer. A metallization of the metal top layer can be formed out of a film and/or a sheet comprising copper and/or aluminum and/or an alloy of copper and/or an alloy of aluminum. This can also apply to the metal bottom layer which can be formed as a copper and/or aluminum plate and/or a corresponding alloy, for example. The substrate can be designed as a ceramic substrate basing on AlN, Si3N4, or Al2O3 with top and bottom metallization made of aluminum or copper or a corresponding alloy.

Molded semiconductor packages are a widely used, cost-effective encapsulation technology for integrated circuits, but also for power semiconductor devices, especially in the low power range. Such packages can have a transfer molded body being prepared from thermosetting resin like epoxy resin. Terminals are partially embedded in the molded body.

The terminals of such packages may have a comparably small thickness of 0.15-0.25 mm providing a certain flexibility for compensation of height irregularities when mounting the molded packages and of mechanical or thermomechanical stress in module operation, for example.

The described semiconductor power module may realize a large molded power package with a large molded body size of up to 70×70 mm\hat{ }2 applicable for higher power classes like E-mobility, for example. The corresponding terminals may form broad power terminals with a thickness of up to 2 mm and a width of up to 25 mm. It is a finding in the context with the present disclosure that when mounting such a power package e.g. to a busbar in an inverter setup, these thick power terminals may be deformed to compensate for height tolerances. Because of their relatively large thickness, a deformation of such terminals provides strong mechanical forces also on those portions of the terminals, which are embedded in the molded package body, and consequently on the molded body in the vicinity of the terminals. This this is accompanied by the risk of crack formation and outbreaks in a hard and brittle molded epoxy body.

Due to the described configuration of the terminal and the reinforcement member embedded in the molded body of the housing, a stable semiconductor power module is feasible that enables reliable functioning even for high voltage power module applications and even for large sized module bodies and terminals with a reduced risk of crack formation in critical areas, in particular where the one or more terminals emerge from the molded body. A corresponding semiconductor power module is also suitable for applications, where power modules are exposed to mechanical and thermal stress during installation and/or operation and even if it is exposed to mechanical and thermal stress during installation and/or operation.

According to an embodiment of the semiconductor power module, wherein the material of the reinforcement member may comprise an elastic modulus of 10-100 MPa. It is a finding in the context with the present disclosure that material with such elastic modulus can effectively compensate or dissipate bending forces.

According to an embodiment the reinforcement member can made of or comprises rubber and/or a resin and/or another elastic material. Alternatively or additionally, the material of the reinforcement member can comprise a hard resin, a hard organic and/or inorganic material. For example, the reinforcement member can be made of or comprise a reinforced glass fiber material. Alternatively or additionally, the material of the reinforcement member can comprise a metal, for example steel. A relatively soft material of the reinforcement member may realize a damping element which smoothly dissipates mechanical forces. It may also provide a better sealing against humidity and/or hazardous gases even in case of stronger bonding of the terminal. A relatively hard material of the reinforcement member may realize a stability enhancing element which absorbs mechanical forces and/or causes better distribution of stress such that adjacent portions of the molded body are not exposed to mechanical stress exposed to significantly reduced mechanical stress. The choice of material for the reinforcement member to be formed can also depend on the intended application of the semiconductor power module. The reinforcement member forms an additional separate element to the terminal which is directly or indirectly connected thereto.

According to a further embodiment of the semiconductor power module, the reinforcement member is formed by at least one of molding, coating and printing. In this respect, a fluid or past-like soft material may realize a raw material of the reinforcement member to be formed. Alternatively or additionally, the reinforcement member can be formed by or comprise a prefabricated element that is attached to the at least one terminal by at least one of clamping, gluing and soldering.

According to a further embodiment of the semiconductor power module, the reinforcement member is formed with a given material, thickness, width and depth in coordination with a material, thickness and a width of the associated at least one terminal. For example, with respect to a lateral direction the reinforcement member can comprise a depth with a value of 5-15 mm or up to 25 mm. The depth is related to a longitudinal direction of a plate-like terminal towards the molded body. Accordingly, a width of the reinforcement member is related to the other lateral direction along the side wall of the molded body, and a height or thickness of the reinforcement member is related to the stacking direction perpendicular to the depth and the width. The thickness of the reinforcement member can have a value of 0.5-2.5 mm. The width of the reinforcement member can have a value of 2-30 mm. The width of the reinforcement member can also have a value to cover or enclose two or more terminals.

The aforementioned dimensions of the reinforcement member can also depend on the location and shape of the reinforcement member. According to a further embodiment the reinforcement member is configured such that it partially or completely surrounds the at least one terminal. The reinforcement member can be completely embedded in the molded body or can be arranged flush with the side wall of molded body or partly protruding from molded body. The reinforcement member can be arranged on one surface of the terminal or on two or more surfaces of the terminal. The reinforcement member can completely surround the one or more neighbored terminals. Accordingly, the width of the reinforcement member can be formed in coordination with a width of the one or more terminals that may have a respective width of up to 25 mm, for example. The thickness of the reinforcement member can also be formed in coordination with a thickness of the one or more terminals. For example, the terminal has a thickness of 2.5 mm and the reinforcement member completely surrounds the terminal with a thickness of up to 2 mm. Consequently, with respect to the stacking direction, the thickness combination of the terminal and the surrounding reinforcement member on both sided of the terminal would sum up to 6.5 mm.

According to a further embodiment of the semiconductor power module, the reinforcement member comprises at least one of a chamfer and rounding and oblique surface at an edge that is facing away from the wall of the molded body. Alternatively or additionally, the reinforcement member can comprise a chamfer, a rounding and/or an oblique surface at another edge inside the molded body. It is a finding in the context with the present disclosure that edge structures can beneficially affect the compensation or dissipation of unwanted mechanical stress and bending forces.

According to a further embodiment, the semiconductor power module comprises two or more terminals that are electrically coupled to the substrate and at least partly surrounded or covered by the molded body of the housing such that each terminal is integrally coupled and embedded in the molded body and partially protrudes from the wall of the molded body. Thereby, the terminals embedded in the molded body form a molded terminal block. The reinforcement member is configured such that it partially or completely surrounds the terminals inside the molded body at their exit positions. In this respect, if there are three terminals embedded in the molded body next to each other and if each terminal has a respective width of 25 mm, the reinforcement member can continuously cover and/or enclose all three terminals comprising a width of 80 mm or more, for example. Accordingly, in view of isolating issues the material of the reinforcement member between two adjacent terminals should comprise an isolating material.

According to an embodiment, a method for manufacturing a semiconductor power module comprises providing a substrate and at least one terminal that is electrically coupled to the substrate. The method further comprises providing a reinforcement member that comprises a material different from a material of the at least one terminal, and providing a housing with a molded body and coupling the housing to the substrate, the reinforcement member and the at least one terminal, such that the molded body surrounds the substrate, the reinforcement member and the at least one terminal. The material of the reinforcement member is also different from a material of the molded body. The at least one terminal is integrally coupled and at least partly embedded in the molded body and partially protrudes from a wall of the molded body.

The reinforcement member is mechanically coupled to the at least one terminal and is at least in part integrally coupled and embedded in the molded body at the position or region the at least one terminal protrudes from the wall of the molded body.

As a result of that the described method enables the manufacturing of an embodiment of the aforementioned semiconductor power module, described features and characteristics of the semiconductor power module are also discloses for the manufacturing method and vice versa. Thus, the present disclosure comprises several aspects, wherein every feature described with respect to one of the aspects is also disclosed herein with respect to the other aspect, even if the respective feature is not explicitly mentioned in the context of the specific aspect.

According to an embodiment of the method, the step of providing and coupling the reinforcement member to the at least one terminal comprises forming the reinforcement member on one or more surfaces of the at least one terminal by means of e.g. molding, coating and/or printing. Alternatively or additionally, the method comprises providing the reinforcement member with a prefabricated element and attaching the reinforcement member to the at least one terminal by means of e.g. clamping, gluing and/or soldering and/or any other applicable joining process.

The described configurations of the of the terminals and the reinforcement member embedded in the molded body enable to reduce local stress in the molded body in the vicinity of the respective terminal in case of bending or deformation of the terminal during installation and/or operation of the power module. This is achieved by the additional reinforcement member being arranged at and/or around the associated terminal at an end of the embedded portion of the terminal, where the terminal penetrates the sidewall of the molded body. The reinforcement member is embedded in the molded body except towards outside, so that the outer surface may be flush with the sidewall of the molded body, or it may partly extend outside the molded body.

The reinforcement member is made by a material, which is different from the material of the power or auxiliary terminals. Depending on the intended application, the material of the reinforcement member may be a soft and elastic material like rubber to provide flexibility and sealing against humidity and/or hazardous gases even in case of stronger bending of the terminal. Alternatively, the reinforcement member may be made of a hard resin with specified mechanical properties. Also other hard materials like metals or hard inorganic materials are considerable.

The described configurations enable advantages in particular in view of a semiconductor power module forming a relative large molded power package, wherein one or more reinforcement members are arranged on one or more terminals. Especially for relative thick power terminals, a compensation of height tolerances accompanied by bending or deformation of the terminals during mounting of the terminals, e.g. to the busbar structure of an inverter, is provided. Despite of relative high mechanical forces acting also on embedded terminal portions, a crack formation inside the molded body can be prevented or reduced at least due to the compensated or dissipated mechanical and/or thermomechanical stress. The described configurations further allows for compensation of vibrations during operation and any other mechanical impact.

The described configurations of the semiconductor power module can be used in E-mobility products, for example. Alternatively or additionally, the semiconductor power module can be used as well for products, which are realized as large molded power packages like e-mobility products, or for power module housings or terminal blocks, where comparably thick terminals are embedded in any kind of resin material. Further uses with molded power packages are possible as well.

Exemplary embodiments are explained in the following with the aid of schematic drawings and reference numbers. The figures show:

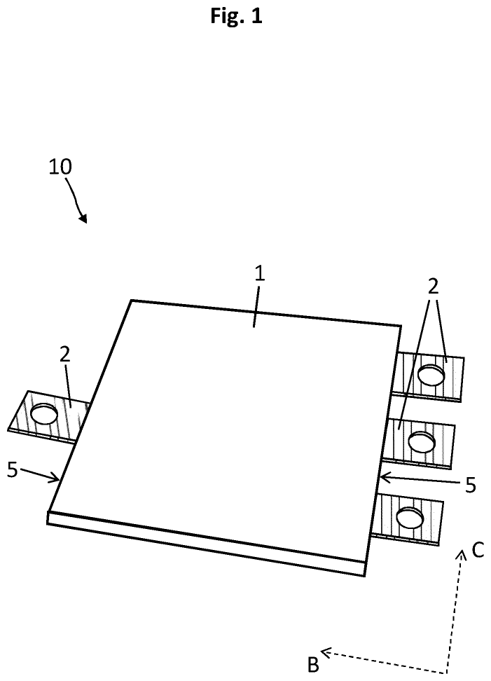

FIG. 1 embodiment of a semiconductor power module in a schematic side view;

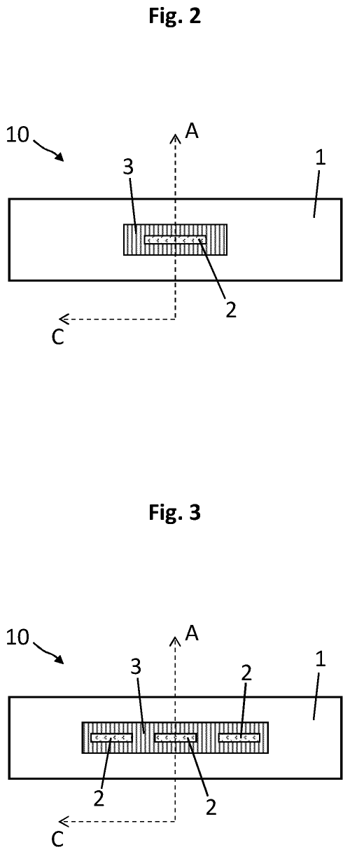

FIGS. 2-8 embodiments of the semiconductor power module in different views;

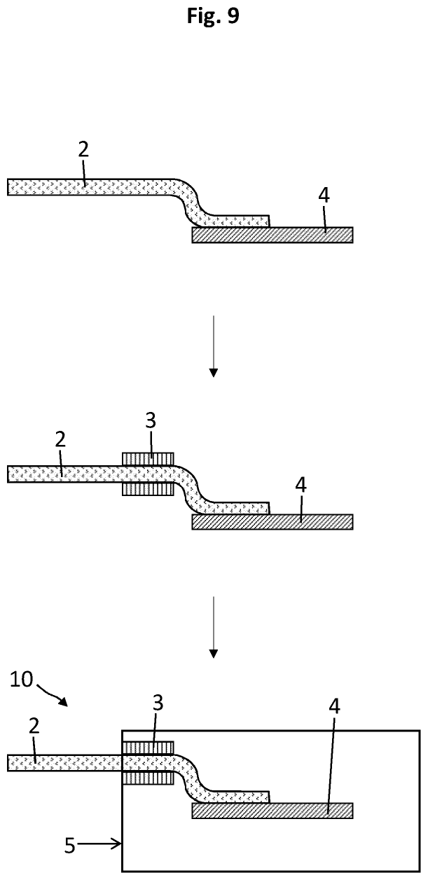

FIG. 9 steps of a method for manufacturing an embodiment of the semiconductor power module, and

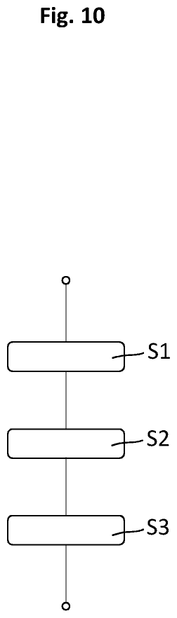

FIG. 10 a flow chart for a method for manufacturing an embodiment of the semiconductor power module.

The accompanying figures are included to provide a further understanding. It is to be understood that the embodiments shown in the figures are illustrative representations and are not necessarily drawn to scale. Identical reference numbers designate elements or components with identical functions. In so far as elements or components correspond to one another in terms of their function in different figures, the description thereof is not repeated for each of the following figures. For the sake of clarity elements might not appear with corresponding reference symbols in all figures possibly.

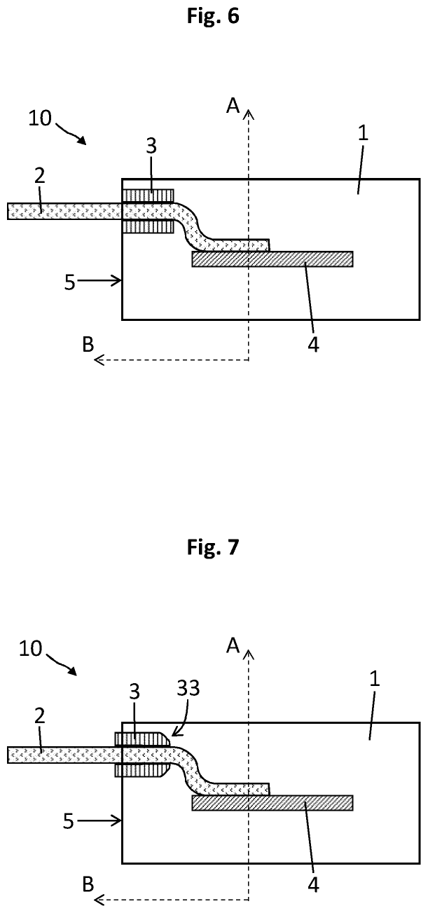

FIG. 1 illustrates in a perspective view an embodiment of a semiconductor power module 10 for a semiconductor device. According to further embodiments, the semiconductor power module 10 can comprise alternative forms as the one shown in FIG. 1. The semiconductor power module 10 comprises a substrate 4 and four main or power terminals 2 that are electrically coupled to the substrate 4 (see FIGS. 6-9). There can also be one or more auxiliary terminals typically thinner and narrower than the power terminals 2. According to alternative embodiments, the semiconductor power module 10 can comprise only one terminal 2 or two or more terminals 2.

The semiconductor power module 10 further comprises a reinforcement member 3 that comprises a material different from a material of the terminals 2 (see FIGS. 2-9). The semiconductor power module 10 further comprises a housing realized as or comprising a molded body 1. The molded body 1 partly or completely surrounds the substrate 4, the reinforcement member 3 and the at least one terminal 2 such that the terminals 2 are integrally coupled and embedded in the molded body 1 and partially protrude from a wall 5 of the molded body 1 (see FIGS. 2-9). The material of the reinforcement member 3 is also different from a material of the encapsulating molded body 1. The reinforcement member 3 is mechanically coupled to the terminals 2 such that it is at least in part integrally coupled and embedded in the molded body 1 at the position or at a region the terminals 2 protrude from the wall 5 of the molded body 1.

As explained by the following FIGS. 2-10, the semiconductor power module 10 is feasible with enhanced stability and enables reliable functioning even for high voltage power module applications and even for large sized terminals and modules with a reduced risk of crack formation in critical areas during installation and operation of the semiconductor power module 10, in particular in critical areas where the terminals 2 emerge from the molded body 1.

FIG. 2 illustrate an embodiment of the semiconductor power module 10 in view along a lateral direction B onto the wall 5. The wall 5 of the molded body 1 the terminal 2 protrudes from a side wall with respect to lateral directions B and C and a stacking direction A of the semiconductor power module 10 (see FIGS. 1 and 6-9). The lateral directions B and C realize horizontal directions and relate to the main plane of extent of the semiconductor power module whereas the stacking direction A realize a vertical direction perpendicular to the lateral directions B and C as illustrated in the FIGS. 1-8.

According to the embodiment as shown in FIG. 2 the terminal 2 is completely surrounded by the reinforcement member 3 with respect to the illustrated lateral direction C and stacking direction A. This also applies to the embodiment shown in FIG. 3, wherein three terminals 3 are embedded spaced apart and next to each other in the molded body 1 protruding along the lateral direction B. The terminals 3 and the molded body 1 can form a terminal structure or a terminal block and may realize a part of a housing of the semiconductor power module 10.

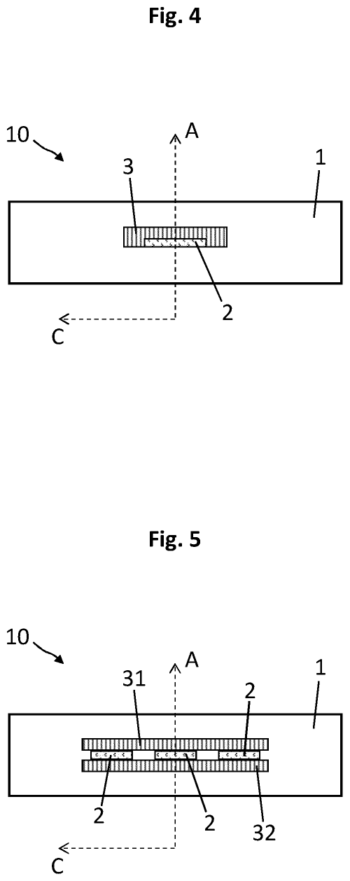

The reinforcement member 3 is configured such that it completely surrounds each terminal 2 with respect to the illustrated lateral direction C and stacking direction A. In this respect, the reinforcement member 3 should be made of or comprise an isolating material to prevent an unwanted electrical connection between the terminals 2. Alternatively, the three terminals 2 can be individually surrounded by a reinforcing member 3 as indicated in the FIGS. 2 and 4, for example.

FIG. 4 shows a further embodiment of the semiconductor power module 10, wherein the terminal 2 is partially surrounded by the reinforcement member 3 with respect to the illustrated lateral direction C and stacking direction A. The reinforcement member 3 is directly arranged on a top side and on both lateral sides of the terminal 2.

FIG. 5 shows a further embodiment of the semiconductor power module 10, wherein three terminals 2 are covered at their top side and bottom side by the reinforcement member 3 with respect to the illustrated lateral direction C and stacking direction A. The reinforcement member 3 comprises a first reinforcement element 31 and a second reinforcement element 32 which can form two separate plate-like elements or a common continuous U-shaped element with respect to the stacking direction A and the lateral direction B.

The FIGS. 6-9 illustrate embodiments of the semiconductor power module 10 in respective cross section views along the lateral direction C onto a plane spanned by the lateral direction B and stacking direction A. The reinforcement member 3 can be configured flush with an outer surface of the side wall 5 (see FIG. 6) or it can protrude from the side wall 5 (see FIG. 7).

FIG. 7 further illustrates that the reinforcement member 3 can comprise a chamfer or rounding or oblique surface 33 at an edge that is facing away from the side wall 5 of the molded body 1 and/or any other edge inside the molded body 1. Such an edge structure can beneficially affect the compensation or dissipation of unwanted mechanical stress and bending forces acting on the molded body 1.

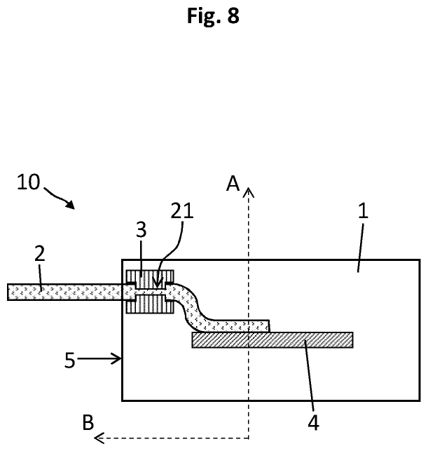

FIG. 8 illustrates that the terminal 2 can comprise a recess or thinned area 21 for further stress reduction and/or improved fixation of the reinforcement element 3 and the reinforcement member 3 can be configured in coordination with the terminal 2 such that it engages in the recess or thinned area 21. The thinned area 21 on the terminal 2 and the reinforcement element 3 can protrude out of the molded body 1 for better stress relief, for example.

FIG. 9 illustrates possible manufacturing steps in order to form the semiconductor power module 10. Steps of a corresponding manufacturing method can follow the flow chart as shown in FIG. 10. In a step S1 the substrate 4 and at least one terminal 2 are provided, wherein the terminal 2 is electrically coupled to the substrate 4.

In a step S2 the reinforcement member 3 is provided and attached to the terminal 2 at a predetermined position. For example, the reinforcement member is formed on one or more surfaces of the terminal 2 by means of molding, coating and/or printing. Alternatively or additionally, the reinforcement member is provided with one or more prefabricated elements and the reinforcement member can be attached to the terminal 2 by means of clamping, gluing and/or soldering or any other applicable joining method.

In a step S3 the housing with the molded body 1 is provided and coupled to the substrate 4, the reinforcement member 3 and the terminal 2, such that the molded body 1 surrounds the substrate 4, the reinforcement member 3 and at least partly the terminal 2. The step S3 can include providing a molding substance as a raw material to form the molded body 1 by means transfer or injection molding, for example. The molding substance can be a thermoplastic or thermosetting resin, or any other resin material. The material can comprise fillers like particles or fibers.

Thus, the molded body 1 is formed around the substrate 4, the reinforcement member 3 and the terminal 2, such that the terminal 2 is integrally coupled and embedded in the molded body 1 and partially protrudes from the side wall 5. The reinforcement member 1 is mechanically coupled to the terminal 2 and is integrally coupled and embedded in the molded body 1 at the position or region the terminal 2 protrudes from the side wall 5.

The semiconductor power module 10 realizes a molded power package wherein the molded body 1 form an encapsulation the one or more terminals 2 are partly embedded in. The reinforcement member 3 is arranged at or close to an end portion of an embedded section of the terminal 2 next to the side wall 5 of the molded body 1.

The reinforcement member 3 forms an additional element to the associated terminal 2 made of a material, which is different from the material of the terminal 2 prepared around the complete cross section of the terminal 2, for example. The material of the reinforcement member 3 is also different from a material of the molded body 1. Alternatively, an arrangement of the reinforcement member 3 only on one or two or three surfaces like a top and a bottom surfaces of the terminal 2 is possible as well. The additional reinforcement member 3 may be prepared by an additional molding or forming step in case of the use of rubber or resin material, but also by any other method like coating or printing. The molded body 1 can be transfer or injection molded using epoxy resin to form an encapsulation for the whole package structure.

The reinforcement member 3 contributes to reduce mechanical stress within a hard and brittle epoxy molded body 1 in the vicinity of the respective terminals 2, when a force is applied on an outer part of the terminal 2, e.g. due to welding, screwing, or other fixation methods. Additionally, it can compensate mechanical stress during operation caused e.g. by vibrations or thermal impact. So a certain tolerance compensation without or at least reduced crack generation in the molded body 1 is available when mounting the semiconductor power module 10 in a customer application like an inverter.

Another way of manufacturing the reinforcement member 3 is to place the terminal 2 in a molding tool such that it gets embedded into molded body 1 leaving a cavity at an end portion. Then the cavity can filled by a raw material forming the reinforcement member 3.

A fillet or a chamfer or oblique side surface 33 of the reinforcement member 3 can contribute to a mechanically improved design. the fillet or a chamfer 33 may be introduced to provide an improved stress reduction on critical positions at an interface between the terminal 2 and the molded body 1, e.g. next to an inner embedded end of the reinforcement member 3 (see FIG. 7). Alternatively or additionally, the terminal 2 may have the thinned portion or area 21 in the region of the reinforcement member 3 which provides a further reduction of the internal stress and which may also provide an improved fixation of the reinforcement member 3, especially when a comparably soft and elastic material is chosen for the reinforcement member 3 (see FIG. 8).

As shown in the FIGS. 1, 3 and 5 there can be several terminals 2 neighbored to each other, e.g. in the arrangement of a leadframe, and there is the opportunity of a common reinforcement member 3 embedding two or more neighbored terminals 2 under formation of a kind of a terminal block. In view of such a design, the reinforcement member 3 is made of an electrically isolating material.

The reinforcement member may be prepared from every applicable material, which differs from the material of the respective terminal 2 and the molded body 1. The material choice depends on the purpose of the use of the reinforcement member. The material may be a soft and/or elastic material, for example with a Young modulus lower than the Young modulus of the molded body, to provide high flexibility, but also an improved sealing against humidity or hazardous gases even in the situation of a strong bending of the terminal 2. Alternatively or additionally, the material may be a hard material with a high elastic modulus, for example with a Young modulus higher than the Young modulus of the molded body, like a hard resin, a metal or another hard organic or inorganic material. In general, the applicability of a material for a reinforcement member 3 depends on its elastic or Young modulus with respect to the purpose of use.

In view of a displacement at an outer tip of the terminal 2, which causes a bending of the terminal 2, dependent on the elastic or Young modulus of the material of the reinforcement member 3 resulting mechanical stress is compensated or dissipated differently. For example, a rubber material can have an elastic modulus varying between 10 MPa and 100 MPa. In view of a relative soft material with an elastic modulus below 1 MPa there might be less impact on the stress situation in the molded body 1 next to the terminal 2, especially with respect to maximum stress in molded body 1 next to the terminal 2 and the reinforcement member 3. An improved configuration can be set by an extended bending length of the terminal 2, where the maximum stress is transferred from a location next to an edge of the molded body 1 towards the module interior next to an inner interface between the reinforcement member 3 and molded body 1. Moreover, a reliable sealing is provided even in case of strong bending of the terminal 2.

Further, a beneficial configuration in view of the stress situation especially with respect to the maximum stress in the molded body 1 can be achieved, when the elastic modules of the material of the reinforcement member 3 exceeds 1 MPa. Then, stress in the molded body 1 in a vicinity of the terminal can be significantly reduced and distributed with an increasing elastic modulus of the reinforcement material.

A further improvement of the stress situation may be achieved when using a rigid material with a relative high elastic modulus like a hard resin, a metal, or another isolating hard material, for example the reinforcement member 3 is made of steel with an elastic modulus of 200 GPa. Accordingly, mechanical stress can mostly be absorbed inside the reinforcement member 3 and kept away from the epoxy molded body 1. So, due to the steel reinforcement member 3 there is nearly no stress transmitted to a brittle molded body 1 whereas higher stress level occurs inside the reinforcement member 3.

The described and illustrated configurations are particularly suitable for large transfer molded power packages with relative thick terminals 2, for example having a thickness of up to 12 mm with respect to the stacking direction A. Nevertheless, the described and illustrated configurations can be used for other applications, where one or more terminals 2 are embedded in resin material as it is the situation in frames or covers of epoxy or gel filled power modules or in terminal blocks. The terminals 2 can be embedded in a body, e.g. made of fiber-reinforced thermoplastic or thermosetting resin material, which is prepared by transfer or injection molding.

The embodiments shown in the FIGS. 1 to 9 as stated represent exemplary embodiments of the improved semiconductor power module 10, and the manufacturing method for; therefore, they do not constitute a complete list of all embodiments. Actual arrangements and methods may vary from the embodiments shown in terms of metal substrate structures and power modules, for example.

### REFERENCE SIGNS

1 molded body
2 terminal
21 thinned area of the terminal
3 reinforcement member
31 first reinforcement element
32 second reinforcement element
33 chamfer/rounding of the reinforcement member
4 substrate
5 side wall
10 semiconductor power module
A stacking direction
B lateral direction
C lateral direction
S(i) steps of a method for manufacturing a semiconductor power module

1. A semiconductor power module, comprising:
substrate and at least one terminal that is electrically coupled to the substrate,
a reinforcement member that comprises a material different from a material of the at least one terminal, and
a housing with a molded body that surrounds the substrate, the reinforcement member and the at least one terminal such that the at least one terminal is integrally coupled and embedded in the molded body and partially protrudes from a wall of the molded body, wherein the reinforcement member is mechanically coupled to the at least one terminal such that it is at least in part integrally coupled and embedded in the molded body at the position the at least one terminal protrudes from the wall of the molded body.

2. The semiconductor power module according to claim 1, wherein the reinforcement member is configured such that it completely surrounds the at least one terminal.

3. The semiconductor power module according to claim 1, wherein the reinforcement member is formed by at least one of molding, coating and printing.

4. The semiconductor power module according to claim 1, wherein the reinforcement member is formed by a prefabricated element that is attached to the at least one terminal by at least one of clamping, gluing and soldering.

5. The semiconductor power module according to claim 1, wherein the reinforcement member is formed with a given material, thickness, width and/or depth in coordination with a material, thickness and/or width of the at least one terminal.

6. The semiconductor power module according to claim 1, wherein the material of the reinforcement member comprises an elastic modulus of 10-100 MPa.

7. The semiconductor power module according claim 1, wherein the material of the reinforcement member comprises at least one of rubber and resin.

8. The semiconductor power module according to claim 1, wherein the material of the reinforcement member comprises metal.

9. The semiconductor power module according to claim 1, wherein with respect to a lateral direction of the semiconductor power module the reinforcement member comprises a depth with a value of 5-25 mm.

10. The semiconductor power module according to claim 1, wherein with respect to a stacking direction (A) perpendicular to lateral directions (B, C) of the semiconductor power module (10) the reinforcement member (3) comprises a thickness with a value of 0.5-2.5 mm.

11. The semiconductor power module according to claim 1, wherein the reinforcement member comprises at least one of a chamfer, rounding and oblique surface at an edge that is facing away from the wall of the molded body.

12. The semiconductor power module according to claim 1, comprising two or more terminals that are electrically coupled to the substrate surrounded by the molded body of the housing such that the terminals are integrally coupled and at least partly embedded in the molded body and partially protrude from the wall of the molded body, wherein the reinforcement member is configured such that it partially or completely surrounds the terminals.

13. A method for manufacturing a semiconductor power module, comprising:
providing a substrate and at least one terminal that is electrically coupled to the substrate,
providing a reinforcement member that comprises a material different from a material of the at least one terminal, and
providing a housing with a molded body and coupling the housing to the substrate, the reinforcement member and the at least one terminal, such that the molded body surrounds the substrate, the reinforcement member and the at least one terminal partly and the at least one terminal is integrally coupled and embedded in the molded body and partially protrudes from a wall of the molded body, wherein the reinforcement member is mechanically coupled to the at least one terminal and is at least in part integrally coupled and embedded in the molded body at the position the at least one terminal protrudes from the wall of the molded body.

14. The method according to claim 13, wherein providing and coupling the reinforcement member to the at least one terminal comprises:
forming the reinforcement member on one or more surfaces of the at least one terminal by means of at least one of molding, coating and printing.

15. The method according to claim 13, wherein providing and coupling the reinforcement member to the at least one terminal further comprises:
positioning the at least one terminal inside a molding tool providing a cavity for forming the reinforcement member,
forming the reinforcement member by means of molding to the terminal inside the provided cavity, and
forming the molded body by means of molding to the terminal and/or to the reinforcement member.

16. The method according to claim 13, wherein providing and coupling the reinforcement member to the at least one terminal comprises:
providing the reinforcement member with a prefabricated element,
attaching the reinforcement member to the at least one terminal by means of at least one of clamping, gluing and soldering.

17. The method according to claim 13, comprising:
providing the at least one terminal without a reinforcement member,
forming the molded body around the at least one terminal such that a cavity is available around the at least one terminal, and
filling the cavity around the at least one terminal by at least one of filling, material injection using a nozzle and a molding process.
